(19) United States
(12) Patent Application Publication
(10) Pub. No.: US 2008/0042154 A1
(43) Pub. Date: Feb. 21, 2008

(54) LIGHT-EMITTING DEVICE, METHOD OF FABRICATING THE SAME, AND ELECTRONIC APPARATUS

(75) Inventor: Hiromi Wano, Atsugi-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/746,133

(22) Filed: May 9, 2007

(30) Foreign Application Priority Data
May 16, 2006 (JP) 2006-136168

(51) Int. Cl. H01L 21/00; H01L 33/00

(52) U.S. Cl. 257/98; 438/31; 257/E33.069

(57) ABSTRACT

A light-emitting device is provided in which a plurality of thin films including a light-emitting layer are stacked. The light-emitting device includes a waveform structure having a directive scattering function in one interface between the thin films.

### BACKGROUND

1. Technical Field

The present invention relates to a light-emitting device, a method of fabricating the same, and an electronic apparatus.

2. Related Art

Light-emitting devices such as organic electro-luminescence devices (hereinafter, referred to organic EL devices) are being used as display devices for electronic apparatuses such as cellular phones, personal computers, and PDAs (Personal Digital Assistants) and exposure heads in image forming devices such as digital copy machines and printers. An example of a light-emitting device is one having a multi-layered structure formed by stacking a plurality of thin films with a variety of refractive indexes including a light-emitting layer.

The refractive index of the light-emitting layer is different in accordance with a material, but it is generally in the range of 1.55 to 2.3 or so at 550 nm and is larger than those of air (n=1.0) and a glass material (n=1.5). Accordingly, light emitted from a layer of high refractive index passes an interface between a layer of high refractive index and a layer of low refractive index at least once in order to reach the air layer (n=1.0) on the viewer side, whereby light mostly propagates in a guided mode in a width direction of a substrate due to a total reflection of the interface, and thus does not contribute to display.

To date, several technologies have been used to induce a scattering effect, a diffractive effect, and a photonic crystal effect and suppress a total reflection of emitted light so as to increase the amount of light that propagates in a radiation mode by forming an uneven structure or a microscopic periodic structure in one interface between stacked thin films (see JP-A-2001-76864 and JP-A-2004-22438).

In a technology disclosed in JP-A-2001-76864, an uneven structure is formed on a glass substrate so as to avoid optical confinement, which improves light extraction efficiency. Specifically, the uneven structure is formed using a sacrificed oxide film. Additionally, in a technology disclosed in JP-A-2004-22438, as a top emission structure, a reflection layer of a lower substrate has an uneven structure, and a refractive index of a layer planarizing the uneven structure is larger than that of a light-emitting layer. According to these known technologies, complicated processes are needed to form a microscopic structure and planarize an upper portion of the structure.

### SUMMARY

An advantage of some aspects of the invention is to provide a configuration which can provide the same directive scattering effect and the like with a simpler configuration. Another advantage of some aspects of the invention is to provide a method which can provide the same directive scattering effect and the like with a simpler process.

According to an aspect of the invention, there is provided a light-emitting device in which a plurality of thin films including a light-emitting layer are stacked. The light-emitting device includes a waveform structure having a directive scattering function in one interface between the thin films.

According to the light-emitting device, by forming the waveform structure having the directive scattering in one interface of layers in the light-emitting device, it is possible to decrease light which is reflected totally on an interface between layers of a high refractive index and a low refractive index, and increase light radiated to the air.

The waveform structure may include a plurality of convex and concave portions randomly disposed and the convex and concave portions have a smooth surface, that is, an unevenness structure without an edge.

It is possible to perform the directive scattering effect more certainly by employing the waveform structure.

It is preferable that the distance between adjacent convex portions in the waveform structure is in the range of 300 nm to 1200 nm.

It is possible to appropriately scatter each light of colors by forming the distance between adjacent convex portions by the wavelength range of visible light as described above. When the distance between adjacent convex portions is less than 300 nm, near-UV light is most strongly directively scattered. However, it becomes a structure that visible light is not directively scattered, so there is a case that the directive scattering effect can not be obtained. When the distance between adjacent convex portions is 1200 nm or more, near-IR light is most strongly directively scattered, and it becomes a structure that visible light is not directively scattered, so there is a case that the directive scattering effect can not be obtained.

It is preferable that the distance between adjacent convex portions in the waveform structure is in the range of −250 nm to +250 nm centered around a peak wavelength of a spectrum of an emission color in the light-emitting layer.

It is possible to appropriately scatter the emission color by forming the distance between adjacent convex portions in the waveform structure to be in the range of −250 nm to +250 nm from the peak wavelength of the spectrum of the emission color. When the distance between adjacent convex portions is less than −250 nm from the peak wavelength of the spectrum of the emission color, the directive scattering is not exhibited in every peak wavelength of the spectrum of the emission color, so there is a case that the effect can not be obtained. Likewise, when the distance between adjacent convex portions is +250 nm or more from the peak wavelength of the spectrum of the emission color, the directive scattering effect is not exhibited in every peak wavelength of the spectrum of the emission color, so there is a case that the directive scattering effect can not be obtained.

It is preferable that the height between a convex top portion and a concave bottom portion in the waveform structure is in the range of 50 nm to 500 nm.

As mentioned above, when the height between the convex top portion and the concave bottom portion is less than 50 nm, there is a case that the directive scattering effect, is not exhibited sufficiently. When the height between the convex top portion and the concave bottom portion is 500 nm or more, there is a case that a planarization process of forming a planarization layer and the like becomes difficult.

It is preferable that the waveform structure occupies 30% or more of the total area of the interface between the thin films.

It is possible to more certainly perform the directive scattering effect by employing the waveform structure. When the waveform structure occupies less than 30% of the total area of the interface between the thin films, there is a case that light can not be sufficiently scattered.

According to another aspect of the invention, there is provided a method of fabricating a light-emitting device in which a plurality of thin films including a light-emitting layer are stacked, and the light-emitting device includes a waveform structure having a directive scattering function in one interface between the thin films. The method includes a waveform structure forming process of forming a film made of mesoporous silica by the use of a spin coat method, and forming the waveform structure.

According to the method, it is possible that the waveform structure formed out of the mesoporous silica is simply formed and a directive scattering mechanism is simply formed as well.

It is preferable that the film formed out of the mesoporous silica is designed so as to be in the range of 10 nm to 300 nm in the waveform structure forming process.

In the waveform structure which is formed so as to have the above-mentioned film thickness, the height between a convex top portion and a concave bottom portion is in the range of 50 nm to 500 nm, and it is possible to appropriately exhibit the directive scattering effect,

The waveform structure forming process includes depositing a silicon alkoxide solution having a solid content in the range of 3 wt % to 8 wt % by the use of the spin coat method with the number of rotations in the range of 1500 rpm to 4000 rpm, and performing a baking process in vacuum at the temperature of 300 to 400° C. for 0.5 to 5 hours.

It is possible to simply and certainly form the waveform structure by employing the processes. That is, it is possible to certainly form the waveform structure by setting the solution content supplied by the spin coat method with the number of rotations and the baking condition at the time of forming a film to the above-mentioned range in the waveform structure forming process.

According to another aspect of the invention, there is provided an electronic apparatus including the light-emitting device. It is possible for the electronic apparatus to achieve a highly visible display by the use of the light-emitting device.

### BRIEF DESCRIPTION OF THE DRAWINGS

The invention will be described with reference to the accompanying drawing, wherein like numbers reference like elements.

FIG. 1 is a schematic diagram illustrating a wiring structure of an organic EL panel related to an organic EL device according to the embodiments of the invention.

FIG. 2 is a top plan view illustrating a configuration of the organic EL panel related to the organic EL device according to the embodiments of the invention.

FIG. 3 is a sectional view illustrating a configuration of an organic EL element according to a first embodiment of the invention.

FIG. 4 is a top plan view schematically illustrating a configuration of a waveform structure constituting the organic EL element according to the first embodiment.

FIG. 5 is a side view schematically illustrating the configuration, of the waveform structure constituting the organic EL element according to the first embodiment.

FIG. 6 is a diagram illustrating a detected result of directive scattered light of 450 nm in transmission of a directive scattering layer according to the first embodiment.

FIG. 7 is a diagram illustrating a detected result of directive scattered light of 450 nm in refraction of the directive scattering layer according to the first embodiment.

FIG. 8 is a table illustrating a correlation between a depth of a waveform structure and an angle of a directive scattering at 450 nm.

FIG. 9 is a diagram illustrating a detected result of directive scattered light of 550 nm in transmission of the directive scattering layer according to the first embodiment.

FIG. 10 is a diagram illustrating a detected result of the directive scattered light of 550 nm in refraction of the directive scattering layer according to the first embodiment.

FIG. 11 is a diagram illustrating a detected result of directive scattered light of 650 nm in transmission of the directive scattering layer according to the first embodiment.

FIG. 12 is a diagram illustrating a detected result of the directive scattered light of 650 nm in refraction of the directive scattering layer according to the first embodiment.

FIG. 13 is a sectional view schematically illustrating a configuration of an organic EL element according to a second embodiment of the invention.

FIG. 14 is a sectional view schematically illustrating a configuration of an organic EL element according to a third embodiment of the invention.

FIG. 15 is a sectional view schematically illustrating a configuration of an organic EL element according to a fourth embodiment of the invention.

FIG. 16 is a graph of an energy radiated to the air on the viewer side with respect to the current density when displaying a white, in the organic EL element according to the first embodiment.

FIG. 17 is a table illustrating a measurement result of a chromaticity when observed in the direction of 0° and 45° and a blue pixel XB is turned on, in the organic EL element according to the first embodiment.

FIG. 18 is a table illustrating a measurement result of a chromaticity when observed in the direction of 0° and 45° and a white is displayed, in the organic EL element according to the first embodiment.

FIG. 19 is a sectional view schematically illustrating a configuration of an organic EL element according to a fifth embodiment of the invention.

FIG. 20 is a sectional view schematically illustrating a configuration of an organic EL element according to a sixth embodiment of the invention.

FIG. 21 is a sectional view schematically illustrating a configuration of an organic EL element according to a seventh embodiment of the invention.

FIG. 22 is a sectional view schematically illustrating a configuration of an organic EL element according to an eighth embodiment of the invention.

FIG. 23 is a graph illustrating a peak wavelength of a spectrum of an emission color of an organic EL layer.

FIGS. 24A and 24B are diagrams illustrating a detected result of directive scattered light of 650 nm in transmission and refraction of a directive scattering layer according to a ninth embodiment.

FIGS. 25A and 25B are diagrams illustrating a transmission characteristic and a refraction characteristic, respectively, when a cycle of a waveform is changed with respect to a wavelength of different incident light.

FIG. 26 is a sectional view schematically illustrating a configuration of an organic EL element according to the ninth embodiment of the invention.

FIG. 27 is a sectional view schematically illustrating a configuration of an organic EL element according to a tenth embodiment of the invention.

FIG. 28 is a sectional view schematically illustrating a configuration of an organic EL element according to an eleventh embodiment of the invention.

FIG. 29 is a sectional view schematically illustrating a configuration of an additional modified example of an organic EL element.

FIG. 30 is a sectional view schematically illustrating a configuration of an additional modified example of an organic EL element.

FIG. 31 is a sectional view schematically illustrating a configuration of an organic EL element according to a twelfth embodiment of the invention.

FIG. 32 is a sectional view schematically illustrating a configuration of an additional modified example of an organic EL element.

FIG. 33 is a sectional view schematically illustrating a configuration of an additional modified example of an organic EL element.

FIG. 34 is a sectional view schematically illustrating a configuration of an additional modified example of an organic EL element.

FIGS. 35A, 35B, and 35C are diagrams illustrating electronic apparatuses including the organic EL device according to the embodiments of the invention.

### DESCRIPTION OF EXEMPLARY EMBODIMENTS

Hereinafter, an embodiment of the invention will be described in detail with reference to the accompanying drawings.

This embodiment shows an aspect of the invention, does not limit the invention, and may be modified in various forms without departing from the technical scope of the invention. Additionally, in the below drawings, in order to enable layers and members to be a recognizable size on the drawings, different scales are used depending on the layers and the members.

### Organic EL Panel

First of all, an organic EL panel of a light-emitting device according to embodiments of the invention will be described.

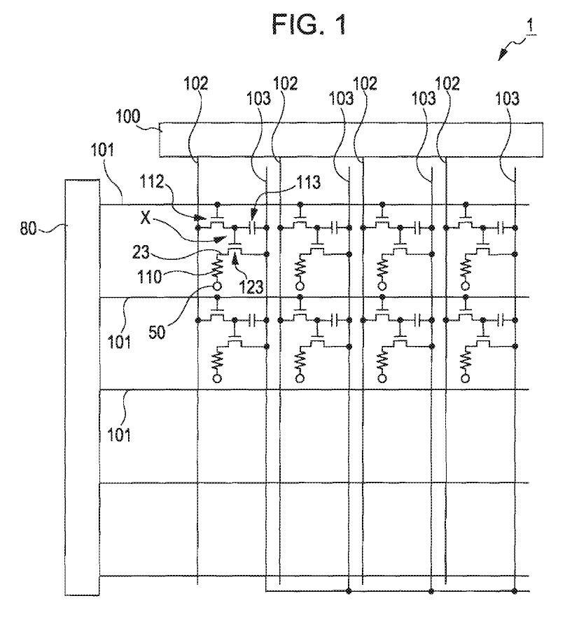

FIG. 1 is a schematic diagram illustrating a wiring structure of an organic EL panel 1.

The organic EL panel 1 of the embodiment is an active matrix system which uses thin-film transistors (hereinafter, referred to as TFTs.) as switching elements and has a wiring configuration including a plurality of scanning lines 101, a plurality of signal lines 102 extending perpendicular to the scanning lines 101, and a plurality of power lines 103 extending parallel to the plurality of signal lines 102, wherein a pixel X is formed in the proximity of each intersection point of the scanning lines 101 and the signal lines 102.

According to the technical scope of the invention, the active matrix system using TFT and the like is not essential, but it is possible to obtain the same effect when the invention is put into practice by using a substrate for a simple matrix and performing a simple matrix drive.

A data line driving circuit 100 including a shift register, a level shifter, a video line, and an analog switch is connected to the signal lines 102. In addition, a scan-driving circuit 80 including the shift register and the level shifter is connected to the scanning lines 101.

Additionally, each pixel X includes a switching TFT 112 (a switching element) where a scanning signal is provided to a gate electrode via the scanning lines 101, a retention capacitor 113 which keeps a pixel signal provided from the signal lines 102 via the switching TFT 112, a driving TFT 123 (a switching element) where the pixel signal kept by the retention capacitor 113 is provided to the gate electrode, a pixel electrode 23 (a first electrode) to which driving current flows from the power lines 103 at the time of electrically connecting to the power lines 103 via the driving TFT 123, and light-emitting layers 110 interposed between the pixel electrodes 23 and a negative electrode 50 (a second electrode).

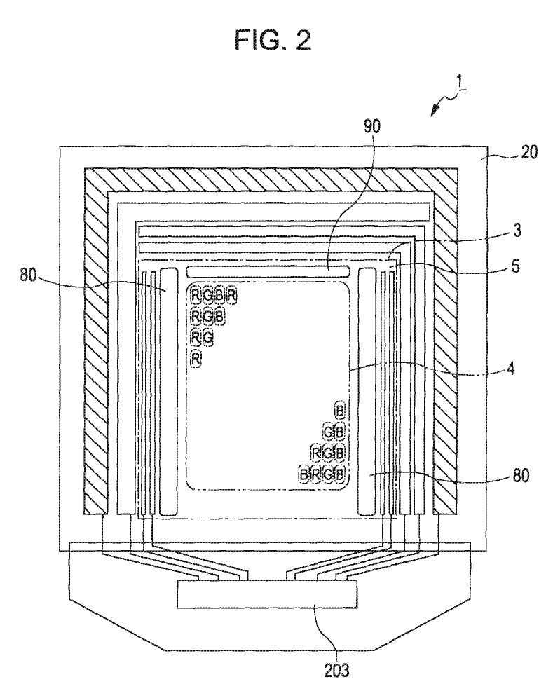

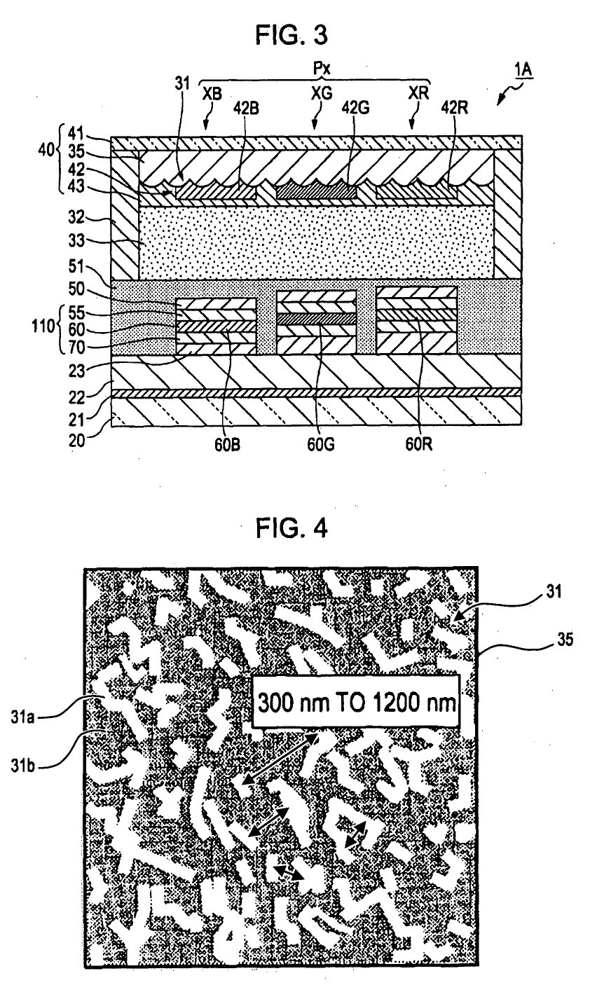

Next, a specific example of an organic EL panel 1 according to an embodiment will be described with reference to FIGS. 2 and 3. Herein, FIG. 2 is a top plan view schematically illustrating a configuration of the organic EL panel 1. FIG. 3 is a sectional view schematically illustrating a unit pixel group of one of a plurality of organic EL elements constituting the organic EL panel 1.

A configuration of the organic EL panel 1 will be described with reference to FIG. 2.

FIG. 2 is a diagram illustrating the organic EL panel 1 which allows the light-emitting layers 110 to emit light by the use of various wirings, TFTs, pixel electrodes, and various circuits formed on a substrate 20.

As shown in FIG. 2, a unit part of the organic EL panel 1 includes the substrate 20 which has an electrical insulation property, the pixel X (see FIG. 1) which is formed by disposing the pixel electrode 2 3 connected to the switching TFT 112 on the substrate 20 in a matrix arrangement, and a pixel portion 3 (within the range of a dashed-dotted line in FIG. 2) which is disposed in at least the pixel X and substantially formed so as to be rectangular in a plan view.

The pixel portion 3 according to the embodiment is partitioned into an actual display region 4 (within the range of a dashed-two dotted line in the drawings) at the center thereof and a dummy region 5 (a region between the dashed-dotted line and the dashed-two dotted line) disposed outside of the actual display region 4.

In the actual display region 4, a red pixel XR, a green pixel XG, and a blue pixel XB which respectively emit a red emission (R), a green emission (G), and a blue emission (B) are regularly disposed in rows from left to right. Additionally, the color pixels XR, XG, and XB are arranged such that columns of the same color are formed. Also, each of the color pixels XR, XG, and XB includes a corresponding one of the light-emitting layers 110 which emits RGB colors in accordance with the operation of the TFTs 112 and 123. One of each of the color pixels XR, XG, and XB form a unit pixel group Px (as described below), thereby enabling full color display to be performed by allowing the unit pixel group Px to perform a color mixture of emitting light of RGB. Therefore, a full color image is displayed in the actual display region 4 which is formed by arranging the unit pixel group Px in the matrix arrangement.

Additionally, the scan-driving circuits 80 are disposed on both sides of the actual display region 4 in FIG. 2. The scan-driving circuits 80 are formed in a lower layer of the dummy region 5.

A detection circuit 90 is disposed in the upper side of the actual display region 4 in FIG. 2, and the detection circuit 90 is formed in a lower layer of the dummy region 5. The detection circuit 90 is a circuit for detecting an operating state of the organic EL panel 1. For example, a detected-information outputting unit (not shown) that outputs detected information is formed so as to perform quality and defect inspection on the organic EL panel 1 at the time of fabrication or shipping,

A driving voltage of the scan-driving circuit 80 and the detection circuit 90 is applied by a predetermined power supply portion via a driving voltage connecting portion (not shovel). Additionally, a driving control signal and the driving voltage of the scan-driving circuit 80 and the detection circuit 90 are respectively transmitted and applied by a predetermined main driver and the like which control the operation of the organic EL panel 1 via a driving control signal connecting portion (not shown) and the driving voltage connecting portion (not shown). In this case, the driving control signal is a command signal from the main driver and the like related to a control when the scan-driving circuit 80 and the detection circuit 90 output a signal.

### First Embodiment

Next, a structure of a unit pixel group of the organic EL element with respect to a first embodiment of the organic EL element constituting an organic EL panel 1 will be described with reference to FIG. 3.

In FIG. 3, the pixel electrodes 23, the light-emitting layers 110, and the negative electrodes 50 constituting a part of the organic EL element corresponding to a pixel will be described in detail, and the driving TFT 123 is connected to the pixel electrodes 23. Additionally, the pixel electrodes 23 constituting the organic EL element are each formed for a red pixel XR, a green pixel XG, and a blue pixel XB. As shown in FIG. 1, each pixel is driven by the driving TFT 123.

As shown in FIG. 3, a unit pixel group Px of the organic EL element (an organic EL device) 1A has the light-emitting layers 110 which are interposed between the pixel electrodes 23 and the negative electrodes 50 on a substrate 20. In addition, a color filter substrate 40 is formed opposite the substrate 20. Each of the electrodes 23 and 50 and the light-emitting layers 110 is disposed between the substrate 20 and the color filter substrate 40. A gap is formed between the substrate 20 and the color filter substrate 40 so that a filler 33 can be used to fill in a region surrounded by a sealing material 32.

Additionally, the light-emitting layers 110 are each formed of different luminous materials with respect to the red pixel XR, the green pixel XG, and the blue pixel XB so that they may emit a red light R, a green light G, and a blue light B, respectively. Also, light emitted from the light-emitting layers 110 is emitted through the color filter substrate 40. Accordingly, the organic EL element 1A (the organic EL panel 1) according to the embodiment is formed so as to be of the top emission type.

The substrate 20 is a transparent substrate, and a glass substrate is used in the embodiment. The material of the glass substrate has a refractive index of 1.54 for light having a wavelength of 550 nm. In addition, a reflection layer 21 which is formed of aluminum layer of a thin film is formed on the substrate 20, and light radiated from the light-emitting layers 110 is reflected toward the color filter substrate 40. For each pixel, a passivation layer 22 is formed on the reflection layer 21, and the corresponding pixel electrode 23 as a positive electrode is formed on the passivation layer 22.

Each of the pixel electrodes 23 is a transparent conducting film of ITO (Indium-Tin Oxide), IZO(Indium Zinc Oxide), or a complex oxide of a tin oxide, an indium oxide, a zinc oxide, or the like. In the embodiment, an ITO film is employed, The ITO film has a refractive index of 1.82 for light having a wavelength of 550 nm.

To form the pixel electrodes 23, a transparent conducting film is formed on the entire surface (actually, it is the entire surface of the substrate 20 with the passivation layer 22 interposed therebetween) of the substrate 20 by means of a sputter method, and then the pixel electrodes 23 corresponding to the red pixel XR, the green pixel XG, and the blue pixel XB are patterned by performing a wet etching process on the resultant film on which a resist mask is formed.

The light-emitting layers 110 are each formed of a laminated body including a hole transporting layer 7 0 (the light-emitting layer) formed on the corresponding pixel electrode 23, an organic EL layer 60 (the light-emitting layer) formed on the hole transporting layer 70, and an electron transporting layer 55 (the light-emitting layer) formed on the organic EL layer 60.

Each of the hole transporting layers 70 is a layer film which has a function of transporting and injecting a hole to the corresponding organic EL layer 60. As a material for forming the hole transporting layers 70, a high-molecular-weight polymer material can be used such as a dispersion of 3,4-polyethylenedioxythiophene/polystyrenesulfonate(PEDOT/PSS), that is, 3,4-polyethylenedioxythiophene is dispersed in polystyrenesulfonate as a dispersion medium, and then the result is dispersed in water again. Finally, the resultant dispersion is appropriately used.

The hole transporting layers 70 are not limited to the above-mentioned material, and may be formed of various materials. For example, a polystyrene, a polypyrrole, a polyaniline, a polyacetylene, a derivate thereof, or the like which is dispersed in an appropriate dispersion medium, such as, polystyrenesulfonate, can be used. As a material for forming the hole-transporting layers 70, a low-molecular-weight material can be used such as a common hole-injecting material, examples of which are a copper phthalocyanine, m-MTDATA, TPD, and α-NPD which can be formed using a deposition method.

As a material for forming the organic EL layers 60, a known luminescence material which can emit a fluorescence or a phosphorescence can be used. In addition, organic EL layers 60R, 60G, and 60B are provided for the red pixel XR, the green pixel XG, and the blue pixel XB, respectively, and thus it is possible for the organic EL element 1A to display a full color display.

Examples of a material for forming the organic EL layers 60 (60R, 60G, and 60B), specifically include a polysilane such as a (poly)fluorene derivative (PF), a (poly)paraphenylenevinylene derivative (PPV), a polyphenylene derivative (PP), a polyparaphenylene derivative (PPP), a polyvinyl carbazole (PVK), a polythiophene derivative, and a polymethylphenylsilane (PMPS) as a high-molecular-weight polymer material, Additionally, a high-molecular-weight polymer material can be used which has been doped with a high-molecular-weight-polymer-based material such as a perylene pigment, a coumarin-based pigment, or a rhodamin-based pigment or a low-molecular-weight material such as a Rubrene, a perillene, 9,10-diphenylarithracene, a tetraphenylbutadiene, a nile red, a coumarin6, or a quinacridone. A host material such as Alq3 or DPVBi as a low-molecular-weight material can be used which has been doped with a nile red, DCM, a rubrene, a perillene, or a rhodamine, or which has been formed using a deposition method. Additionally, the red organic EL layer 60R may be formed of MEHPPV(poly(3-methoxy6-(3-ethylhexyl)paraphenylenevinylene), the green organic EL layer 60G may be formed of a mixed solution of a polydioctylfluorene and F8BT(an alternate copolymer of a dioctylfluorene and a benzothiadizaoles), and the blue organic EL layer 60B may be formed of a polydioctylfluorene.

The electron transporting layers 55 are a layer film which has a function for transporting and injecting an electron to the organic EL layers 60. As a material for forming the electron transporting layers 55, for example, an alkali earth metal such as LiF and SrF2 or an alkali metal compound can be employed,

Each of the negative electrodes 50 is a counter electrode which is opposite the corresponding pixel electrode 23. The negative electrodes 50 include a first negative electrode which is formed of a metal having a low work function formed on the organic EL layers 60 and a second negative electrode which is formed on the first negative electrode so as to protect the first negative electrode. As the metal forming the first negative electrode, it is preferable that the metal has a low work function of 3.0 eV or less. Specifically, it is preferable to use Ca which has a work function of 2.6 eV, Sr which has a work function of 2.1 eV, and Ba which has a work function of 2.5 eV. The second negative electrode is provided so as to protect the first negative electrode from oxygen, moisture, and the like by covering the first negative electrode. Moreover, it is provided so as to increase a conductive property of the entire negative electrode 50. Since the organic EL element 1A according to the embodiment is of the top emission type which acquires emitted light radiated from the color filter substrate 40, the negative electrode 50 has translucency.

Next, the organic EL element 1A which includes the light-emitting layers 110 of various colors between the pixel electrodes 23 and the negative electrodes 50 is sealed by a thin-film sealing layer 51. Additionally, the color filter substrate 40 is formed on the thin-film sealing layer 51 with the filler 33 in a region surrounded by the sealing material 32 interposed therebetween. The color filter substrate 40 includes a substrate 41 which is disposed in a viewing side of the organic EL device 1, a directive scattering layer 35 which is disposed on the substrate 41, a color filter layer 42 which is disposed on the directive scattering layer 35, and an overcoat layer 43 which covers the color filter layer 42.

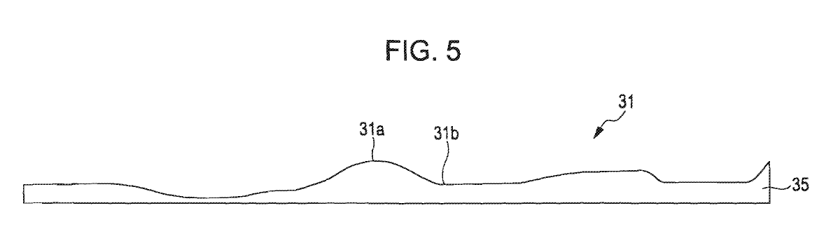

The substrate 41 is a transparent substrate, and a glass substrate is used in the embodiment. A material of the glass substrate has a refractive index of 1.54 for light having a wavelength of 550 nm. Additionally, the directive scattering layer 35 is formed of a mesoporous silica film, and a waveform structure 31 is formed on a surface layer. The waveform structure 31 is formed so as to be capable of performing a directive scattering function. As shown in FIGS. 4 and 5, the waveform structure 31 includes a plurality of uneven structures (convex portions 31a and concave portions 31b) which are randomly disposed, and the uneven structures have a smooth surface.

Herein, in the waveform structure 31, the distance between adjacent convex portions 31a is in the range from 300 nm to 1200 nm as shown in FIG. 4. In addition, the height between a top portion of the convex portions 31a and a bottom portion of the concave portions 31b is in the range of 50 nm to 500 nm as shown in FIG. 5. Thanks to the above-described waveform structure 31 it is possible to appropriately perform a directive scattering function. The waveform structure 31 occupies 30% or more of a total area of the directive scattering layer 35.

By including the directive scattering layer 35, the directive scattering function is exhibited in the visible light region. When the waveform structure 31 occupies less than 30% of the total area of the directive scattering layer 35, sometimes the directive scattering is not sufficiently performed in the visible light region. Additionally, when the height between the top portion of the convex portions 31a and the bottom portion of the concave portions 31b are more than 500 nm and the waveform structure 31 is planarized, cracking occurs. As a result, sometimes there is a lack of panel reliability.

The color filter layers 42 of various colors of a red (R), a green (G), and a blue (B) are formed on the directive scattering layer 35. Additionally, the overcoat layer 43 which covers the color filter layers 42 is formed thereon. The substrate 41, the directive scattering layer 35, the color filter layer 42, and the overcoat layer 43 constitute the color filter substrate 40.

In the unit pixel group Px having the above-mentioned configuration, a bank (a partition wall) may be formed between each of the red pixel XR, the green pixel XG, and the blue pixel XB. In this case, it is possible to form a light-emitting layer formed of a high-molecular-weight polymer material by the use of a liquid droplet jet method. Additionally, it is preferable that the bank is formed of an inorganic bank including an inorganic material and an organic bank including an organic material. It is preferable that a surface of the inorganic bank is lyophilic and a surface of the organic bank is hydrophobic. Thus, when the light-emitting layers 110 are formed by the use of the liquid droplet jet method, droplets can be disposed at the gaps between the banks. In addition, the light-emitting layers 110 may be formed of a low-molecular-weight material. In this case, since the light-emitting layers 110 are formed by the use of a mask deposition method, it is not necessary to form the banks. In the light-emitting layers 110 formed of the low-molecular-weight material, it is preferable that a hole transporting layer or an electron injecting buffer layer is included.

In the organic EL element. 1A according to the configuration, when current flows between the pixel electrodes 23 and the negative electrodes 50, the organic EL layers 60 (603, 60G, and 60R) are emitted, and emitted light is emitted to the color filter substrate 40 via the negative electrodes 50. Alternatively, it is reflected on the reflection layer 21 formed on the substrate 20 and emitted to the color filter substrate 40 via the negative electrodes 50. At this time, since the directive scattering layer 35 is formed on the color filter substrate 40, emitted light is appropriately scattered. Therefore, it is possible to widen a viewing angle.

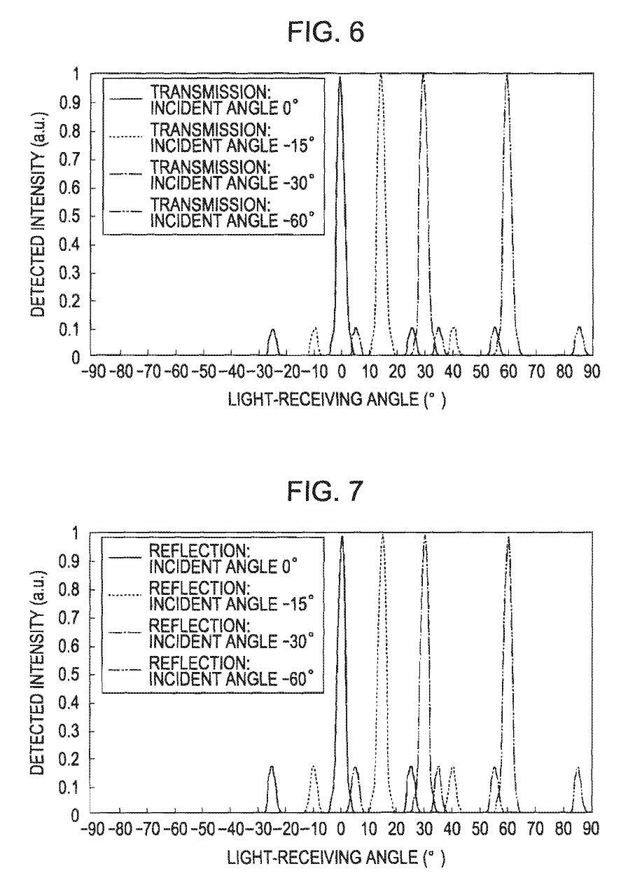

FIG. 6 is a detected result of directively scattered light in transmission when light having a wavelength of 450 nm is incident on the directive scattering layer 35 at various angles of 0°, 15°, 30°, and 60°. The horizontal axis indicates a light-receiving angle (°) and the vertical axis indicates a detected intensity (a.u.). In addition, FIG. 7 is a detected result of directively scattered light in reflection when light having the wavelength of 450 nm is incident on the directive scattering layer 35 at various angles of 0°, 15°, 30°, and 60°. The horizontal axis indicates a light-receiving angle (°) and the vertical axis indicates a detected intensity (a.u.). In FIGS. 6 and 7, the detected intensity in the incident angle in transmission is normalized, and the detected intensity in the specular reflection direction in reflection is normalized.

As mentioned above, according to the directive scattering layer 35 which is used in the embodiment, in the proximity of a wavelength of a blue, a detected peak due to the directive scattering is found in the angle of ±25°, with respect to the direction of incident light or reflected light in transmission and reflection. With the help of the waveform structure 31, the directive scattering is performed. Different from a diffractive effect at the time of forming an uneven structure provided with a regular cycle, some of incident light is scattered with the same directivity at the almost same angle even when the incident angle varies.

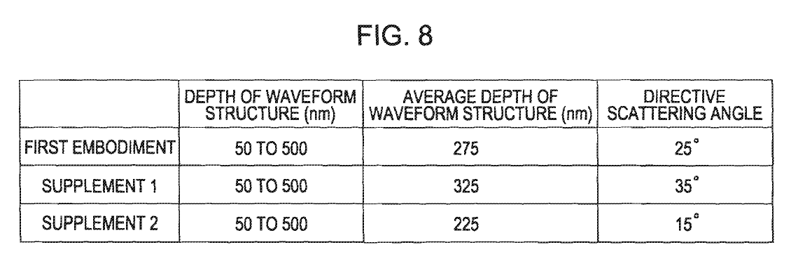

In the embodiment, the detected peak due to the directive scattering is set to be in the angle of ±25° with respect to the direction of incident light or reflected light, but it is possible to control the angle of directive scattered light by changing an average of a depth of a waveform. FIG. 8 shows a correlation between a depth of the waveform structure 31 at 450 nm and an angle of the directive scattering. Accordingly, by changing the average of the depth of the waveform structure 31, the angle of the directive scattering may be multiple.

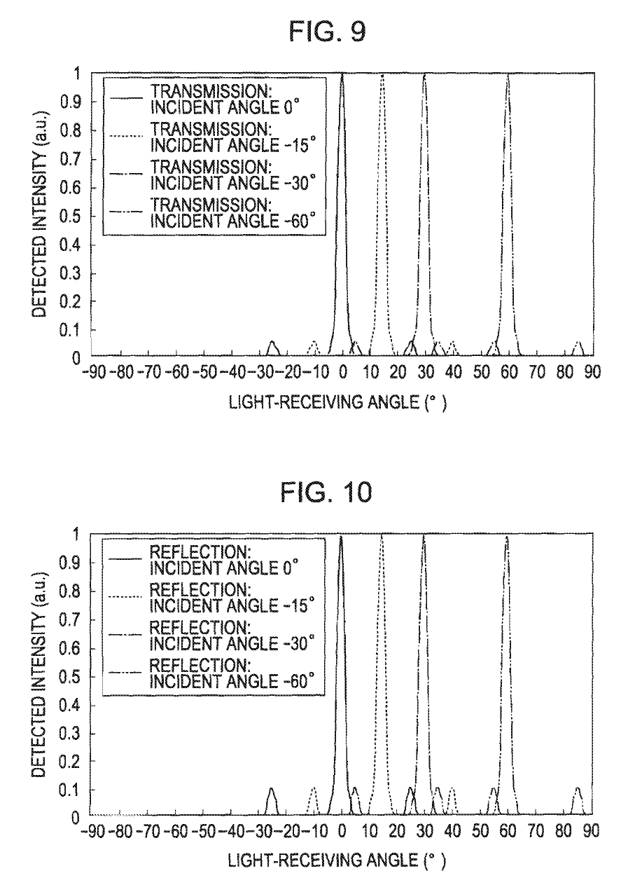

Meanwhile, FIG. 9, is a detected result of directively scattered light in transmission when light having a wavelength of 550 nm is incident on the directive scattering layer 35 at various angles of 0°, 15°, 30°, and 60°. The horizontal axis indicates a light-receiving angle (°) and the vertical axis indicates a detected intensity (a.u.). In addition, FIG. 10 is a detected result of directively scattered light in reflection when light having the wavelength of 550 nm is incident on the directive scattering layer 35 at various angles of 0°, 15°, 30°, and 60°. The horizontal axis indicates a light-receiving angle (°) and the vertical axis indicates a detected intensity (a.u.). In FIGS. 9 and 10, the detected intensity in the incident angle in transmission is normalized, and the detected intensity in the specular reflection direction in reflection is normalized.

As mentioned above, due to the directive scattering layer 35 which is used in the embodiment, in the proximity of a wavelength of a green, a detected peak due to the directive scattering is found in transmission and reflection, so it is possible to obtain the directive scattering. However, in comparison with the wavelength of the green, it is possible to obtain more directive scattering effect in the vicinity of the wavelength of the blue than that of the green.

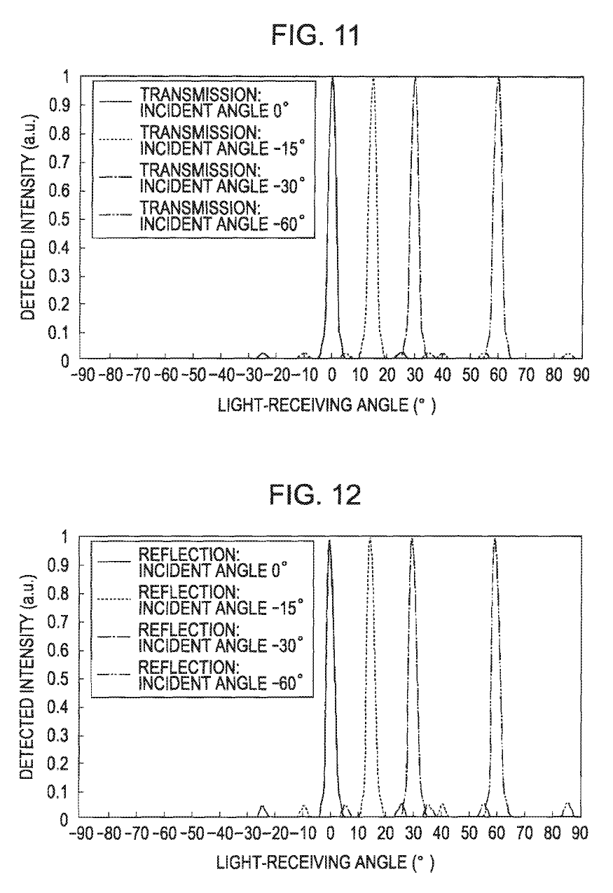

FIG. 11 is a detected result of directively scattered light in transmission when light having a wavelength of 650 nm is incident on the directive scattering layer 35 at various angles of 0°, 15°, 30°, and 60°. The horizontal axis indicates a light-receiving angle (°) and the vertical axis indicates a detected intensity (a.u.). In addition, FIG. 12 is a detected result of directively scattered light; in reflection when light having a wavelength of 650 nm is incident on the directive scattering layer 35 at various angles of 0°, 15°, 30°, and 60°. The horizontal axis indicates a light-receiving angle (°) and the vertical axis indicates a detected intensity (a.u.). In FIGS. 11 and 12, the detected intensity in the incident angle in transmission is normalized, and the detected intensity in the specular reflection direction in reflection is normalized.

As mentioned above, due to the directive scattering layer 35 which is used in the embodiment, in the vicinity of a wavelength of a red, a detected peak due to the directive scattering is found in transmission and reflection, so the directive scattering effect can be obtained. However, in comparison with the wavelength of the red, the more directive scattering effect can be obtained in the vicinity of the wavelength of the blue than that of the red.

Namely, according to the directive scattering layer 35 which is used in the embodiment, the directive scattering effect can be obtained in the blue, green, and red. The problem with the low light extraction efficiency can be solved in the red pixel XR, the green pixel XG, and the blue pixel XB. Additionally, a large directive scattering efficiency and a high directive scattering effect can be obtained in the blue region having a short wavelength, whereby it is possible to largely enhance the light extraction efficiency of the blue, thereby increasing the color temperature of the panel.

A detailed comparison is described in a fourth embodiment as below. However, since the direction of emitted light varies with various angles in the directive scattering layer 35, it is possible to obtain an advantage that a color shift is decreased when viewed from the front side and an angle of the colors in comparison with an organic EL device which does not include the directive scattering layer 35. Specifically, since it is possible for the directive scattering function to obtain a large effect as the wavelength becomes short, it is possible to decrease the color shift in the blue in which a color variation can be easily taken for a brightness variation when viewed in a wide angle. Accordingly, it is possible to enhance a white balance when viewed in a wide angle.

### Second Embodiment

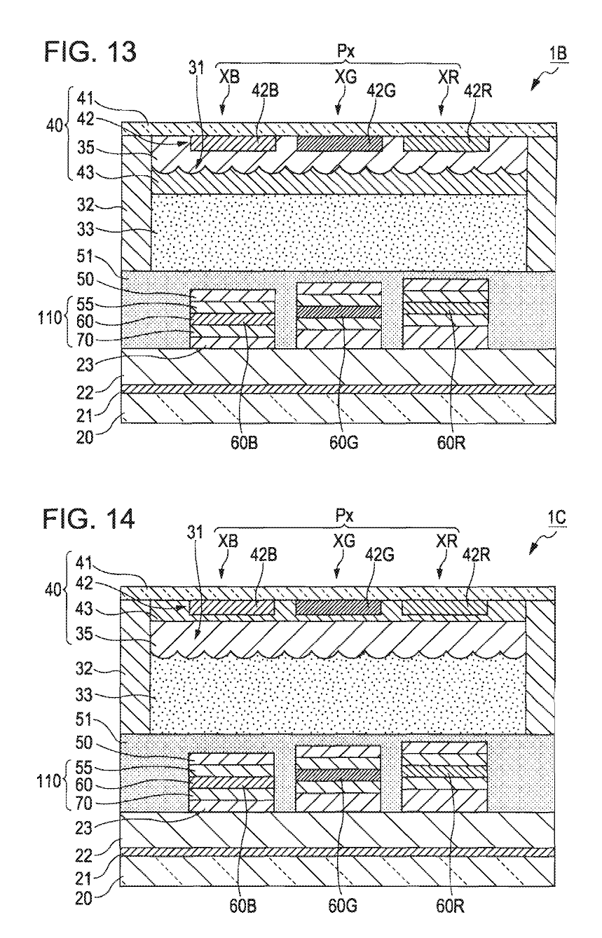

Next, a structure of a unit pixel group of the organic EL element with respect to a second embodiment of the organic EL element constituting an organic EL panel 1 will be described with reference to FIG. 13.

FIG. 13 is a diagram corresponding to FIG. 3 showing the first embodiment of the organic EL element. About the same reference numerals and signs as those shown in FIG. 3, they are formed of the same configuration and member unless there are specific explanations.

In an organic EL element 1B according to the second embodiment, a configuration of the color filter substrate 40 is different from that of the organic EL element 1A according to the first embodiment. Specifically, the color filter substrate 40 includes the substrate 41 which is formed of a transparent member such as glass, the color filter layers 42 (42B, 42G, and 42R) which are formed on the substrate 41, a directive scattering layer 35 which is formed so as to cover the color filter layers 42, and the overcoat layer 43 which is formed on the directive scattering layer 35.

In this case, the directive scattering layer 35 includes a waveform structure 31 and performs an appropriate directive scattering. Therefore, it is possible to solve the problems with the low light extraction efficiency and the low color temperature of the panel.

### Third Embodiment

Next, a structure of a unit pixel group of a organic EL element with respect to a third embodiment of the organic EL element constituting the organic EL panel 1 will be described with reference to FIG. 14.

FIG. 14 is a diagram corresponding to FIG. 3 showing the first embodiment of the organic EL element. About the same reference numerals and signs as those shown in FIG. 3, they are formed of the same configuration and member unless there are specific explanations.

In an organic EL element 1C according to the third embodiment, a configuration of the color filter substrate 40 is different from that of the organic EL element 1A according to the first embodiment. Specifically, the color filter substrate 40 includes a substrate 41 which is formed of the transparent member such as a glass material, the color filter layers 42 (42B, 42G, and 42R) which are formed on the substrate 41, the overcoat layer 43 which is formed so as to cover the color filter layer 42, and a directive scattering layer 35 which is formed on the overcoat layer 43.

In this case, the directive scattering layer 35 includes the waveform structure 31 and performs an appropriate directive scattering. Therefore, it is possible to solve the problems with the low light extraction efficiency, the viewing angle, and the low color temperature of the panel.

### Fourth Embodiment

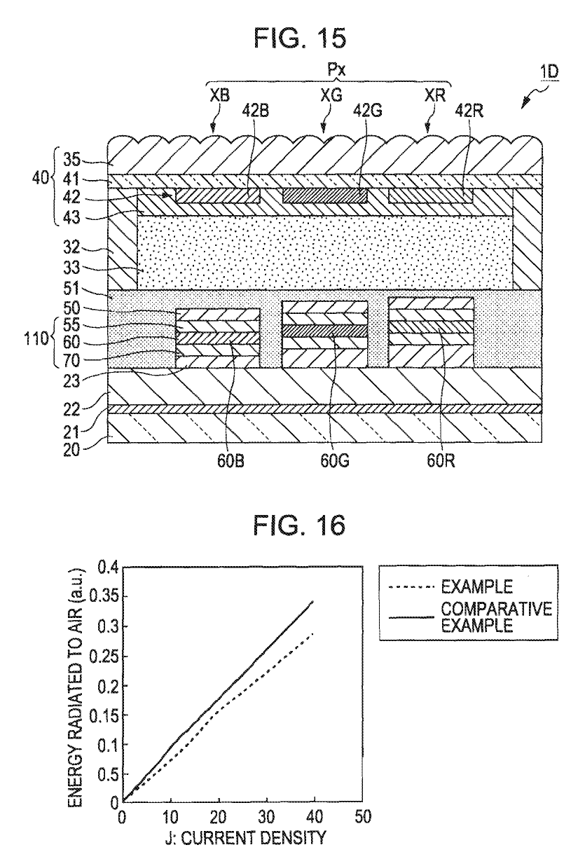

Next, a structure of a unit pixel group of the organic EL element with respect to a fourth embodiment of the organic EL element constituting the organic EL panel 1 will be described with reference to FIG. 15.

FIG. 15 is a diagram corresponding to FIG. 3 showing the first embodiment of the organic EL element. About the same reference numerals and signs as those shown in FIG. 3, they are formed of the same configuration and member unless there are specific explanations.

In an organic EL element ID according to the fourth embodiment, a configuration of the color filter substrate 40 is different from that of the organic EL element 1A according to the first embodiment. Specifically, the color filter substrate 40 includes the substrate 41 which is formed of the transparent member such as a glass material, the color filter layers 42 (42B, 42G, and 42R) which are formed on the substrate 41, the overcoat layer 43 which is formed so as to cover the color filter layers 42, and the directive scattering layer 35 on the other surface of one surface of the substrate 41 on which the color filter layers 42 are formed.

In this case, the directive scattering layer 35 includes the waveform structure 31 and performs an appropriate directive scattering. Therefore, it is possible to solve the problems with the low light extraction efficiency, the narrow viewing angle, and the low color temperature of a panel.

In the embodiments 1 to 4, the color filter layers 42 and the overcoat layer 43 are formed by the use of a coating method such as a spin coat method or a vacuum thin film forming method such as a sputter method and a deposition method.

When the directive scattering layer 35 is not included as before or the directive scattering layer on which the uneven structure is formed in a cycle is included, light radiated from the light-emitting layer is propagated through a glass substrate due to a condition of a total reflection, so that the light extraction efficiency is decreased. However, in the organic EL device 1 according to the embodiment including the directive scattering layer 35, since some of light propagated in the width direction is directively scattered at an angle below the total reflection, light is emitted to the outside of the substrate, the light extraction efficiency is increased, and it is possible to increase the total amount of energy which is radiated to air at the time of an operation under the same current density. FIG. 16 is a graph of energy radiated to air on the viewer side with respect to the current density when turning on total colors of a red (R), a green (G), and a blue (B) so as to display a white. According to an observation of the graph, the organic EL device 1 (an example) according to the embodiment can increase the energy extraction efficiency under the same current density more than a comparative example which does not include the directive scattering layer 35.

Additionally, since the direction of emitted light with various angles varies, in the organic EL device 1 (the example) according to the embodiment which includes the directive scattering layer 35, it is possible to obtain an effect that a color shift decreases when viewed from the front side and an angle of the color more than the comparative example which does not include the directive scattering layer 35. Since it is possible for the directive scattering function to obtain a large effect as the wavelength becomes short, it is possible to decrease the color shift in the blue in which the color variation can be easily taken for the brightness variation when viewed in a wide angle. Accordingly, it is possible to enhance the white balance when viewed in a wide angle.

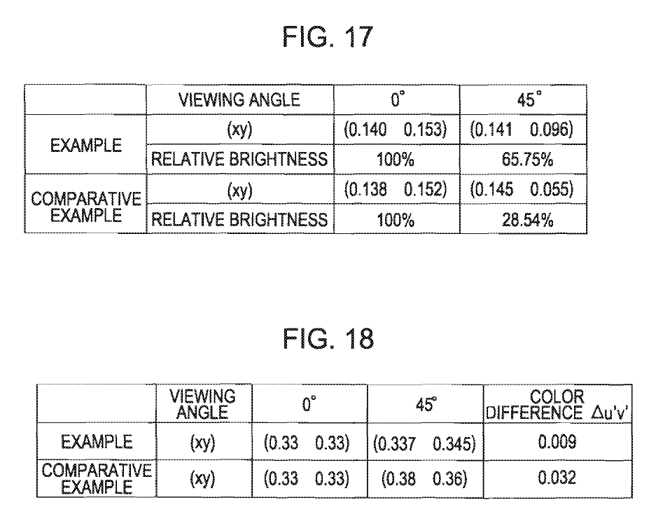

FIG. 17 is a table illustrating a measurement result of a chromaticity when observed in the direction of 0° and 45° and a blue pixel XB is turned on. In the organic EL device 1 (the example) according to the embodiment which includes the directive scattering layer 35, it is possible to know that the color shift largely decreases more than the comparative example which does not include the directive scattering layer 35.

In addition, FIG. 18 is a table illustrating a measurement result of a chromaticity when observed in the direction of 0° and 45° and the red, green, and blue are altogether turned on so as to display the white. In the organic EL device 1 (the example) according to the embodiment which includes the directive scattering layer 35, it is possible to know that the color shift largely decreases more than the comparative example which does not include the directive scattering layer 35 even when the white is displayed.

In the embodiments, the directive scattering layer 35 which has the waveform structure 31 formed on any one of layers of the color filter substrate 40, but the directive scattering layer 35 which has the same waveform structure 31 may be formed on any one of layers of the substrate 20 (that is, the side of the substrate on which the light-emitting layers 110 are formed) on which the pixel electrodes 23 are formed.

### Fifth Embodiment

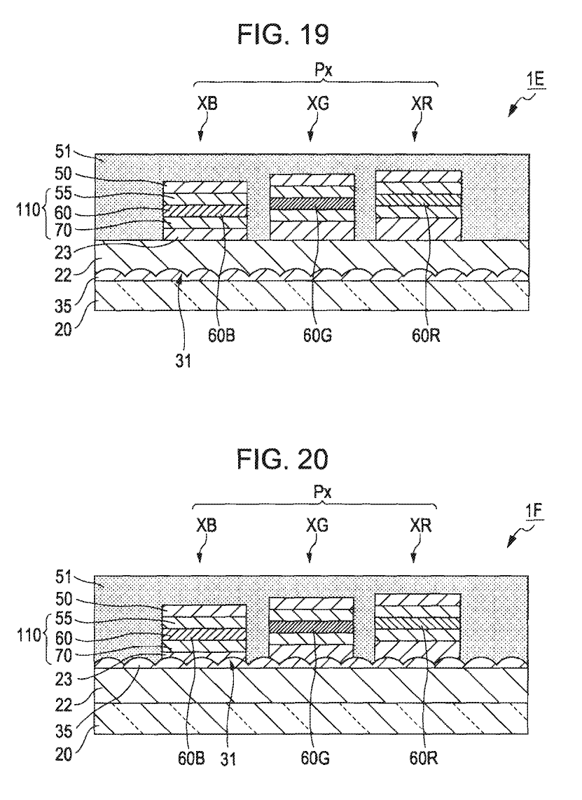

Next, a structure of a unit pixel group of the organic EL element with respect to a fifth embodiment of the organic EL element constituting the organic EL panel 1 will be described with reference to FIG. 19.

FIG. 19 is a diagram corresponding to FIG. 3 showing the first embodiment of the organic EL element. About the same reference numerals and signs as those shown in FIG. 3, they are formed of the same configuration and member unless there are specific explanations.

The organic EL element 1E according to the fifth embodiment is the organic EL element of a bottom emission type, which light radiated from the light-emitting layers 110 is emitted from the substrate 20 including the pixel electrodes 23.

The organic EL element 1E includes the directive scattering layer 35 which is formed on the substrate 20 formed of the transparent material such as glass, and each of the pixel electrodes 23 are formed on all pixels XB, XG, and XR with a predetermined pattern with the passivation layer 22 interposed therebetween, on the directive scattering layer 35. The directive scattering layer 35 includes the waveform structure 31 in the same way as the above-mentioned embodiments and includes the directive scattering function.

The light-emitting layers 110 including the hole transporting layers 70, the organic EL layers 60, and the electron transporting layers 55 and the negative electrodes 50 are formed on the pixel electrodes 23. The sealing layer 51 which covers the laminated bodies of from the pixel electrodes 23 to the negative electrodes 50 is formed on the passivation layer 22. The blue organic EL layer 60B, the green organic EL layer 60G, and the red organic EL layer 60R of the organic EL layers 60 are patterned in all pixels XB, XG, and XR.

Herein, since the organic EL element 1E is of a bottom emission type, the pixel electrodes 23 are formed of a transparent electrical conducting material, for example, ITO (an indium tin oxide). Meanwhile, the negative electrodes 50 are formed of an electrical conducting material having the light reflectivity, for example, aluminum.

In the organic EL element 1E according to the embodiment, the directive scattering layer 35 includes the waveform structure 31 and performs the appropriate directive scattering. Therefore, it is possible to solve the problems with the low light extraction efficiency, the low color temperature of the panel, and the narrow viewing angle.

### Sixth Embodiment

Next, a structure of a unit pixel group of the organic EL element with respect to a sixth embodiment of the organic EL element constituting the organic EL panel 1 will be described with reference to FIG. 20.

FIG. 20 is a diagram corresponding to FIG. 3 showing the first embodiment of the organic EL element. About the same reference numerals and signs as those shown in FIG. 3, they are formed of the same configuration and member unless there are specific explanations.

The organic EL element IF according to the sixth embodiment is the organic EL element of a bottom emission type, which light radiated from the light-emitting layers 110 is emitted from the substrate 20 including the pixel electrodes 23.

The organic EL element IF includes the passivation layer 22 on the substrate 20 which is formed of the transparent material such as glass, and includes the directive scattering layer 35 on the passivation layer 22. The laminated bodies formed of the pixel electrodes 23, the light-emitting layers 110, and the negative electrodes 50 and the sealing layer 51 are formed on the directive scattering layer 35. The directive scattering layer 35 includes the waveform structure 31 in the same way as above-mentioned embodiments and includes the directive scattering function. Herein, since the organic EL element IF is of a bottom emission type, the pixel electrodes 23 are formed of a transparent electrical conducting material, for example, ITO (an indium tin oxide). Meanwhile, the negative electrodes 50 are formed of an electrical conducting material having the light reflectivity, for example, aluminum.

In the organic EL element IF according to the embodiment, the directive scattering layer 35 includes the waveform structure 31 and performs an appropriate directive scattering. Therefore, it is possible to solve the problems with the low light extraction efficiency, the low color temperature of a panel, and the narrow viewing angle.

### Seventh Embodiment

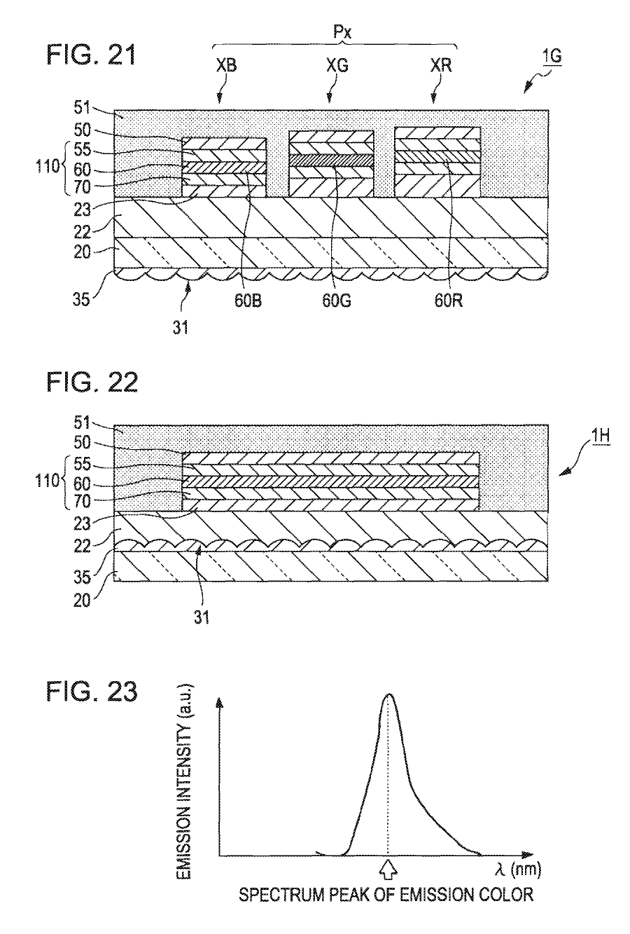

Next, a structure of a unit pixel group of the organic EL element with respect to a seventh embodiment of the organic EL element constituting the organic EL panel 1 will be described with reference to FIG. 21.

FIG. 21 is a diagram corresponding to FIG. 3 showing the first embodiment of the organic EL element. About the same reference numerals and signs as those shown in FIG. 3, they are formed of the same configuration and member unless there are specific explanations.

The organic EL element 1G according to the seventh embodiment is the organic EL element of a bottom emission type, which light radiated from the light-emitting layers 110 is emitted from the substrate 20 including the pixel electrodes 23.

The organic EL element 1G includes the passivation layer 22 on the substrate 20 which is formed of a transparent material such as glass, and includes the directive scatting layer 35 on the other surface (the other surface of the substrate 20) of one surface of the substrate 20 on which the passivation layer 22 is formed. The laminated bodies formed of the pixel electrodes 23, the light-emitting layers 110, and the negative electrodes 50 and the sealing layer 51 are formed on the passivation layer 22. The directive scattering layer 35 includes the waveform structure 31 in the same way as the above-mentioned embodiments and includes the directive scattering function. Herein, since the organic EL element 1G is the bottom emission type, the pixel electrodes 23 are formed of a transparent electrical conducting material, for example, ITO (an indium tin oxide). Meanwhile, the negative electrodes 50 are formed of an electrical conducting material having the light reflectivity, for example, aluminum.

In the organic EL element 1G according to the embodiment, the directive scattering layer 35 includes the waveform structure 31 and performs an appropriate directive scattering. Therefore, it is possible to solve the problems with the low light extraction efficiency, the low color temperature of a panel, and the narrow viewing angle.

A method of forming the directive scattering layer 35

The directive scattering layer 35 used in the above-mentioned embodiments can be formed as a method in the following. Specifically, the waveform structure 31 is obtained by forming the thin film formed of mesoporous silica to be the thickness in the range of 10 nm to 230 nm (for example, 150 nm). Herein, a mesoporous silica film is obtained by performing a spin coat method with the number of 2500 rpm for 30 seconds to a silicon alkoxide solution having a solid content of 5% or so and by performing a baking process in vacuum at a temperature of 350° C. for 1 hour. The mesoporous silica film according to the above method includes the waveform structure 31 and exhibits the scattering function.

In order to design the distance between the convex portions and the height between the top convex portion and the bottom concave portion in the waveform structure 31 to be the above-mentioned range, it is preferable that a solid content of a silicon alkoxide solution is designed to be in the range of 3 wt % to 8 wt %, and the number of rotations of a spin coat, is designed to be in the range of 1500 rpm to 4000 rpm. Additionally, it is preferable that a baking temperature is in the range of 300 to 400° C., and a baking time is for 0.3 to 5 hours.

Other than the above-mentioned method, for example, it is possible to give the waveform structure to the coating film by performing a plasma treatment to a coating film formed of an organic material, an inorganic material, an organic-inorganic hybrid material for a predetermined time (for example, several tens of seconds).

Additionally, it is possible to give the waveform structure to the coating film by polishing the formed coating film by the use of slurry suspension in the range of 0.1 μm to 10 ∞m.

It is possible to give the waveform structure by the use of a deposition method or a sputter method. In the fast film formation rate of 100nm/s, when the film is formed by the use of a vacuum film forming method, there occurs a cluster. Therefore, it is possible to generate the waveform structure in the same way as described above.

Additionally, it is possible to give the waveform structure by burying a resin of a nanoscale size, coating with a coat material having the same refractive index after it is buried, or the like.

Among them, when the mesoporous silica material is used, only the coating process such as the spin coat and the baking process are performed, and thus it is preferable because a load of the process is relatively less.

### Eighth Embodiment

The organic EL panel 1 according to the above-mentioned embodiment includes the blue pixel XB, the green pixel XG, and the red pixel XR so as to display a full color display. However, for example, it is possible to employ a configuration according to the embodiments of the invention for the organic EL panel of a monochromatic bottom-emission type as shown in FIG. 22. FIG. 22 is a schematic diagram illustrating a sectional configuration of an organic EL element 1H of the monochromatic bottom-emission type. FIG. 22 is a diagram corresponding to FIG. 3 showing the first embodiment of the organic EL element. About the same reference numerals and signs as those shown in FIG. 3, they are formed of the same configuration and member unless there are specific explanations.

The organic EL element 1H according to an eighth embodiment includes the single organic EL layer 60 and is an organic EL element of the monochromatic bottom emission type, which light radiated from the light-emitting layer 110 which can emit monochromatic (herein, a blue) light is emitted from the substrate 20 including the pixel electrode 23.

The organic EL element 1H includes the directive scattering layer 35 which is formed on the substrate 20 formed of a transparent material such as glass, and the pixel electrode 23 is formed on the directive scattering layer 35 with the passivation layer 22 interposed therebetween. The directive scattering layer 35 includes the waveform structure 31 in the same way as the above-mentioned embodiments and includes the directive scattering function.

The light-emitting layer 110 including the hole transporting layer 70, the organic EL layer 60, and the electron transporting layer 55 and the negative electrode 50 are formed on the pixel electrode 23. The sealing layer 51 which covers the laminated body of from the pixel electrode 23 to the negative electrode 50 is formed on the passivation layer 22. The organic EL layer 60 is formed of an organic EL material which can emit blue light. Herein, since the organic EL element 1E is the bottom emission type, the pixel electrode 23 is formed of a transparent electrical conducting material, for example, ITO fan indium tin oxide). Meanwhile, the negative electrode 50 is formed of an electrical conducting material having the light reflectivity, for example, aluminum. In the organic EL element 1H according to the embodiment, the directive scattering layer 35 includes the waveform structure 31 and performs an appropriate directive scattering. Therefore, it is possible to solve the problems with the low light extraction efficiency and the narrow viewing angle.

Herein, the waveform structure 31 constituting the directive scattering layer 35 of the organic EL element 1H according to the eighth embodiment is configured to exhibit the direct scattering most strongly in an emission wavelength range of an emission color. FIG. 23 is a graph illustrating a peak wavelength of a spectrum of an emission color of the organic EL layer 60. In the embodiment, the waveform structure 31 includes a random unevenness structure, and a mean value of a cycle of a wave form is substantially made to be within the range of ±250 nm centered around a peak wavelength of a spectrum of an emission color. Namely, since a peak wavelength of an emission spectrum of the organic EL layer 60 according to the embodiment is 420 nm, the mean value of the cycle of the wave form is designed to be in the range of 170 nm to 670 nm.

In the organic EL element 1H, when current flows between the pixel electrode 23 and the negative electrode 50, the organic EL layer 60 emits light, and an emission color (a blue light) is emitted from the substrate 20 via the pixel electrode 23 or an emission color is reflected on the negative electrode 50 and is emitted from the substrate 20 via the pixel electrode 23. At this time, it is possible to widen the narrow viewing angle since the directive scattering layer 35 is formed on the substrate 20.

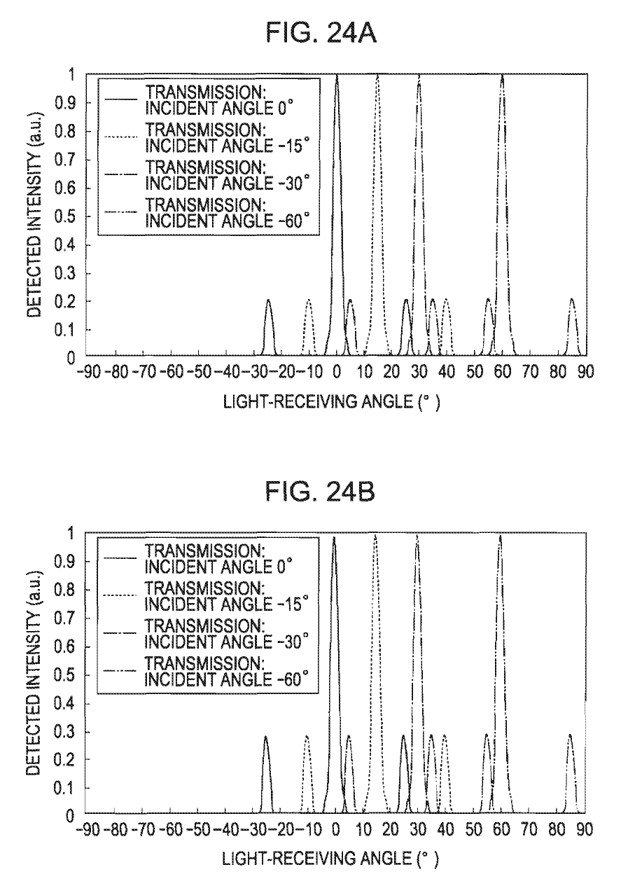

FIG. 24A is a detected result of directively scattered light in transmission when light having a wavelength of 420 nm is incident on the directive scattering layer 35 at various angles of 0°, 15°, 30°, and 60°. The horizontal axis indicates a light-receiving angle (°) and the vertical axis indicates a detected intensity (a.u.). In addition, FIG. 24B is a detected result of directively scattered light in reflection when light having a wavelength of 420 nm is incident on the directive scattering layer 35 at various angles of 0°, 15°, 30°, and 60°. The horizontal axis indicates a light-receiving angle (°) and the vertical axis indicates a detected intensity (a.u.). In FIGS. 24A and 24B, the detected intensity in the incident angle in transmission is normalized, and the detected intensity in the specular reflection direction in reflection is normalized.

As mentioned above, according to the directive scattering layer 35 which is used in the embodiment, in the proximity of a wavelength of a blue, a detected peak due to the directive scattering is found in the angular range of ±25°, with respect to the direction of incident light or reflected light in transmission and reflection. When an average of waveform cycle substantially coincides with the wavelength, the directive scattering occurs strongly. With the help of the waveform structure 31, the directive scattering is performed. Different from a diffractive effect at the time of forming an unevenness structure provided with a regular cycle, some of incident light is scattered with the same directivity at the almost same angle even when the incident angle varies.

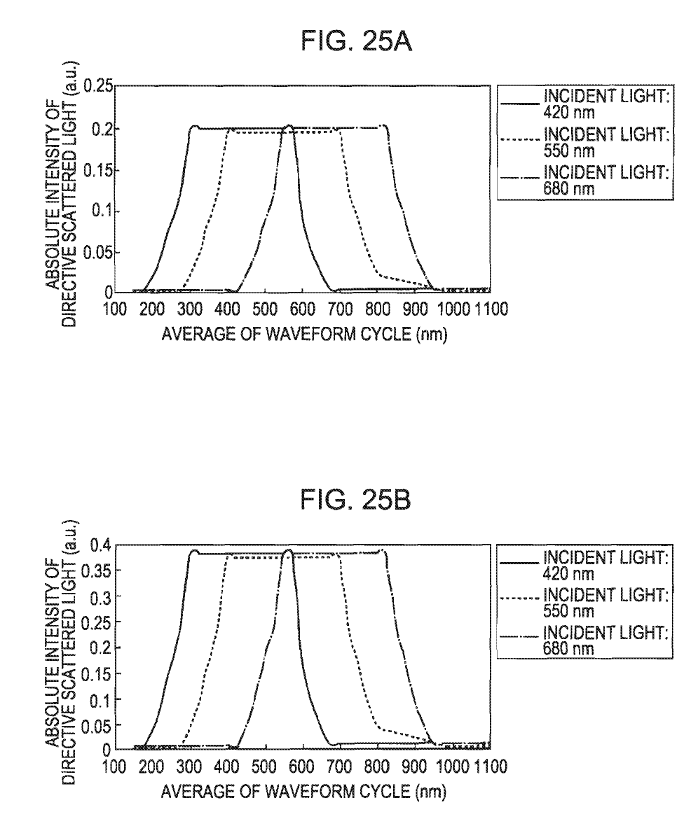

FIG. 25A is a diagram illustrating a transmission characteristic when a waveform cycle is changed to 420 nm, 550 nm, and 680 nm of the wavelength of incident light. FIG. 25B is a diagram illustrating a reflection characteristic when the waveform cycle is changed to 420 nm, 550 nm, and 680 nm of the wavelength of incident light. In FIGS. 25A and 25B, the horizontal axis indicates an average of the waveform cycle, and the vertical axis indicates an absolute intensity of directively scattered light which is detected.

It is possible to form a shape having a different waveform cycle by changing the thickness of the film formed out of mesoporous silica to be in the range of 80 nm to 200 nm. For example, when substantially the thickness of the film formed out of the mesoporous silica is 130 nm, the waveform cycle becomes in the range of 500 nm to 1050 nm. Therefore, it is possible for an average of a cycle to be formed in the range of 650 nm or so.

An average of a waveform cycle in which directively scattered light is not detected in 420 nm, 550 nm, and 680 nm of the wavelength of incident light is the range of 170 nm to 670 nm, the range of 300 nm to 800 nm, and the range of 430 nm to 930 nm, respectively, and is the range of −250 nm to +250 nm with respect to the wavelength of incident light. In the embodiment, the detected peak due to the directive scattering is set be in the angular range of ±25° with respect to the direction of incident light or reflected light, but it is possible to control an angle of directively scattered light by changing an average depth of waveform.

### Ninth Embodiment

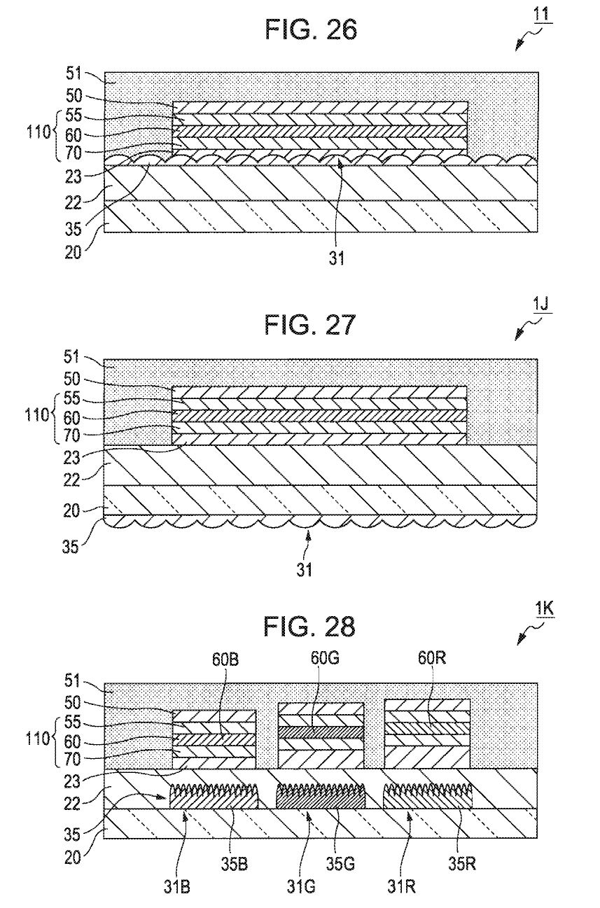

Next, a sectional structure of the organic EL element with respect to a ninth embodiment of an organic EL element constituting an organic EL panel will be described with reference to FIG. 26.

FIG. 26 is a diagram corresponding to FIG. 3 showing the first embodiment of the organic EL element. About the same reference numerals and signs as those shown in FIG. 3, they are formed of the same configuration and member unless there are specific explanations.

The organic EL element 1I according to the ninth embodiment is an organic EL element with a bottom emission type, which light radiated from a light-emitting layer 110 is emitted from a substrate 20 including a pixel electrode 23.

The organic EL element 11 includes a passivation layer 22 on the substrate 20 which is formed of a transparent material such as glass, and includes a directive scattering layer 35 on the passivation layer 22. The laminated body formed of a pixel electrode 23, the monochromatic (a blue) light-emitting layer 110, and the negative electrode 50 and a sealing layer 51 are formed on the directive scattering layer 35. The directive scattering layer 35 includes a waveform structure 31 in the same way as above-mentioned embodiments and includes a directive scattering function. Herein, since the organic EL element 1I is a bottom emission type, the pixel electrode 23 is formed of a transparent electrical conducting material, for example, ITO (an indium tin oxide). Meanwhile, the negative electrode 50 is formed of an electrical conducting material having the light reflectivity, for example, aluminum.

In the organic EL element 1I according to the embodiment, the directive scattering layer 35 includes the waveform structure 31 and performs an appropriate directive scattering. Therefore, it is possible to solve the problems with the low light extraction efficiency and the narrow viewing angle.

### Tenth Embodiment

Next, a sectional structure of the organic EL element with respect to a tenth embodiment of the organic EL element constituting the organic EL panel will be described with reference to FIG. 27.

FIG. 27 is a diagram corresponding to FIG. 3 showing the first embodiment of the organic EL element. About, the same reference numerals and signs as those shown in FIG. 3, they are formed of the same configuration and member unless there are specific explanations.

An organic EL element 1J according to the tenth embodiment is the organic EL element of the bottom emission type, which light radiated from the light-emitting layer 110 is emitted from the substrate 20 including the pixel electrode 23.

The organic EL element 1J includes the passivation layer 22 on the substrate 20 which is formed of a transparent material such as glass, and includes a directive scatting layer 35 on the other surface (the other surface of the substrate 20) of one surface of the substrate 20 on which the passivation layer 22 is formed. The laminated body formed of the pixel electrode 23, the light-emitting layer 110, and the negative electrode 50 and the sealing layer 51 are formed on the passivation layer 22. The directive scattering layer 35 includes the waveform structure 31 in the same way as above-mentioned embodiments and includes the directive scattering function. Herein, since the organic EL element U is the bottom emission type, the pixel electrode 23 is formed of a transparent electrical conducting material, for example, ITO (an indium tin oxide). Meanwhile, the negative electrode 50 is formed of an electrical conducting material having the light reflectivity, for example, aluminum.

In the organic EL element 1J according to the embodiment, the directive scattering layer 35 includes the waveform structure 31 and performs an appropriate directive scattering. Therefore, it is possible to solve the problems with the low light extraction efficiency and the narrow viewing angle, in a blue pixel XB.

As the embodiments 8 and 9, when the passivation layer 22 or the pixel electrode 23 is formed on the waveform structure 31, it is possible to form a layered structure on the upper portion without an occurrence of cracking and the like since the depth of waveform is very small. Additionally, it is possible to form the directive scattering layer 35 including the waveform structure 31 on a surface (that is, the sealing layer 51) on the viewer side. The directive scattering layer 35 constituting the organic EL element in the embodiments 8 to 10 can be formed by forming the thin film out of the mesoporous silica as described above.

### Eleventh Embodiment

Next, a structure of a unit pixel group of the organic EL element with respect to an eleventh embodiment of the organic EL element constituting the organic EL panel will be described with reference to FIG. 28.

FIG. 28 is a diagram corresponding to FIG. 3 showing the first embodiment of the organic EL element. About the same reference numerals and signs as those shown in FIG. 3, they are formed of the same configuration and member unless there are specific explanations.

The organic EL element 1K according to the eleventh embodiment is the organic EL element of the bottom emission type, which light radiated from the light emitting layers 110 is emitted from the substrate 20 including the pixel electrodes 23. Additionally, the blue organic EL layer 60B, the green organic EL layer 60G, and the red organic EL layer 60R of the light-emitting layers 110 are patterned in every pixel so as to display a full color display. A peak wavelength of a blue emission, spectrum is 440 nm, a peak wavelength of a green emission spectrum is 520 nm, and a peak wavelength of a red emission spectrum is 630 nm.

The organic EL element 1K includes the directive scattering layer 35 on the substrate 20 which is formed of a transparent material such as glass, and the passivation layer 22 is formed on the substrate 20 which includes the directive scattering layer 35. The laminated bodies formed of the pixel electrodes 23, the light-emitting layers 110, and the negative electrodes 50 and the sealing layer 51 are formed on the passivation layer 22. Since the organic EL element 1K is the bottom emission type, the pixel electrode 23 is formed of a transparent electrical conducting material, for example, ITO (an indium tin oxide). Meanwhile, the negative electrodes 50 are formed of an electrical conducting material having the light reflectivity, for example, aluminum.

Herein, a blue directive scattering layer 35B, a green directive scattering layer 35G, and a red directive scattering layer 35R of the directive scattering layers 35 are patterned in every pixel. The directive scattering layers 35B, 35G, and 35R have different waveform structures 31B, 31G, and 31R, respectively. Specifically, in the blue directive scattering layer 35B of the blue pixel, a waveform cycle of a waveform structure 31B is substantially in the range of 200 nm to 690 nm, and an average of the waveform cycle is substantially 450 nm. In the green directive scattering layer 35G of the green pixel, a waveform cycle of a waveform structure 31G is substantially in the range of 270 nm to 770 nm, and an average of the waveform cycle is substantially 510 nm. In the red directive scattering layer 35R of a red pixel, a waveform cycle of a waveform structure 31R is substantially in the range of 400 nm to 980 nm, and an average of the waveform cycle is substantially 650 nm.

Such the directive scattering layers 35B, 35G, and 35R can be formed by performing methods such as a spin, a flexography printing, and an ink jet to an alkoxy silane solution several times so that a film thickness out of a mesoporous silica is in the range of 175 nm, 155 nm, and 135 nm.

In the organic EL element 1K according to the embodiment, the directive scattering layers 35B, 35G, and 35R include the waveform structures 31B, 31G, and 31R, and performs the directive scattering appropriately. Therefore, it is possible to solve the problems with the low light extraction efficiency and the narrow viewing angle. Specifically, 1.5 times energy can be supplied to the air layer on the viewer side more than the organic EL element which does not include the directive, scattering layer 35 when the colors R, G, and B are turned on so as to display the white color.

In the embodiment, the directive scattering layer including the waveform structure which corresponds to a wavelength of each color pixel is formed. However, when there is a color which is necessary to increase the extraction efficiency thereof for the purpose of enhancing a color taste of a panel, the directive scattering layer 35 may be selectively formed in a portion corresponding to the pixel.

When there is one color which is necessary to increase the extraction efficiency thereof in a full color organic EL panel and the directive scattering layer 35 including the waveform structure corresponding to the color is formed in the entire surface of the substrate, it is possible to selectively enhance the light extraction efficiency with respect to the color.

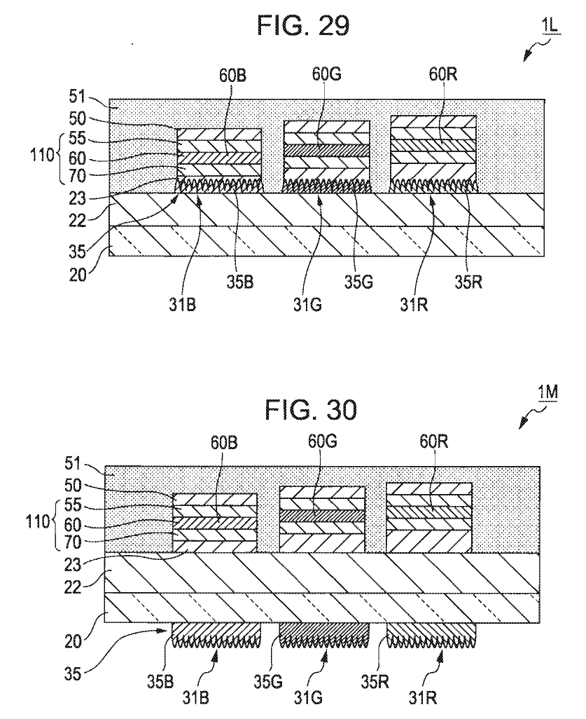

In addition, an interface on which the color directive scattering layer 35B, 35G, and 35R are formed is not limited to the interface between the substrate 20 and the passivation layer 22 as shown in FIG. 28. For example, the respective color directive scattering layers 35B, 35G, and 35R may be formed in an interface between the passivation layer 22 and the pixel electrodes 23 as shown in FIG. 29, and an outer surface (a different surface from the surface on which the passivation layer 22 is formed) of the substrate 20 as shown in FIG. 30.

### Twelfth Embodiment

Next, a sectional structure of the organic EL element with respect to a twelfth embodiment of the organic EL element constituting the organic EL panel will be described with reference to FIG. 31.

FIG. 31 is a diagram corresponding to FIG. 3 showing the first embodiment of the organic EL element. About the same reference numerals and signs as those shown in FIG. 3, they are formed of the same configuration and member unless there are specific explanations.

The organic EL element 1N according to the twelfth embodiment is the organic EL element of the top emission type, which light radiated from the light-emitting layer 110 is emitted from the color filter substrate 40 formed on the negative electrode 50. The light-emitting layer 110 is formed of a monochromatic organic EL layer 60 of the blue. The organic EL element 1N is formed of the monochromatic top emission type, includes the single organic EL layer 60, arid is the organic EL element of the monochromatic top emission type, which light radiated from the light-emitting layers 110 which can emit monochromatic (herein, a blue) light is emitted from a substrate 40 including the blue color filter layer 42B.

The organic EL element 1N includes a reflection layer 21 on the substrate 20 which is formed of a transparent material such as glass, and the pixel electrode 23 is on the reflection layer 21 with the passivation layer 22 interposed therebetween. The light-emitting layer 110 which include the hole transporting layer 70, the organic EL layer 60, the electron transporting layer 55 and the negative electrode 50 are formed on the pixel electrode 23. The sealing layer 51 is formed on the passivation layer 22 so as to cover the laminated body of from the pixel electrode 23 to the negative electrode 50. The filler 33 which is filled in a region surrounded by the sealing material 32 is formed on the sealing layer 51, and the color filter substrate 40 is formed on the upper surface thereof.

The color filter substrate 40 includes a substrate 41, the directive scattering layer 35 disposed in the inner surface (the filler 33 side) of the substrate 41, the blue color filter layer 42B disposed in the inner surface of the directive scattering layer 35, and the overcoat layer 43 in the inner surface of the directive scattering layer 35 including the, color filter layer 42B.

In the organic EL element 1N according to the embodiment, the directive scattering layer 35 includes the waveform structure 31 and performs an appropriate directive scattering. Therefore, it is possible to solve the problems with the low light extraction efficiency and the viewing angle. In the case of the embodiment, since the depth of waveform is very small, it is possible to form a layered structure in the upper portion without an occurrence of cracking and the like.

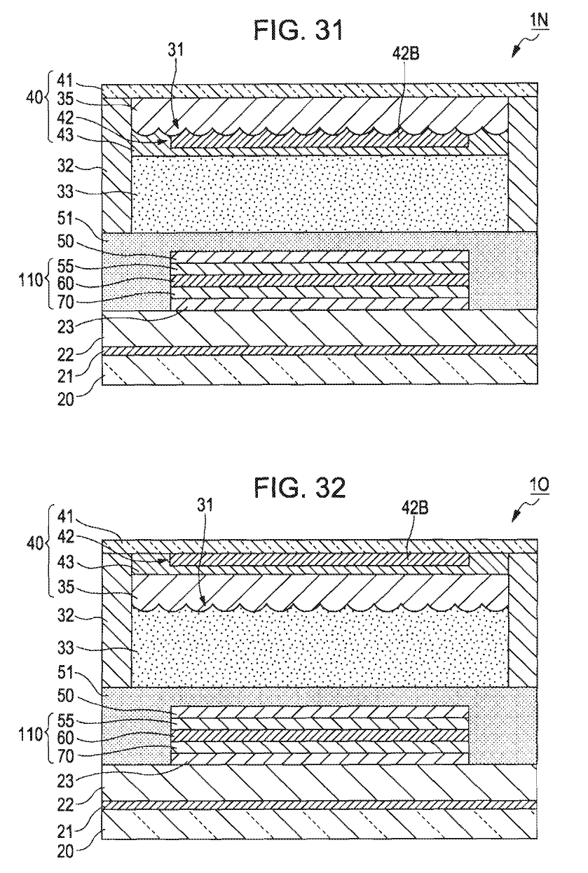

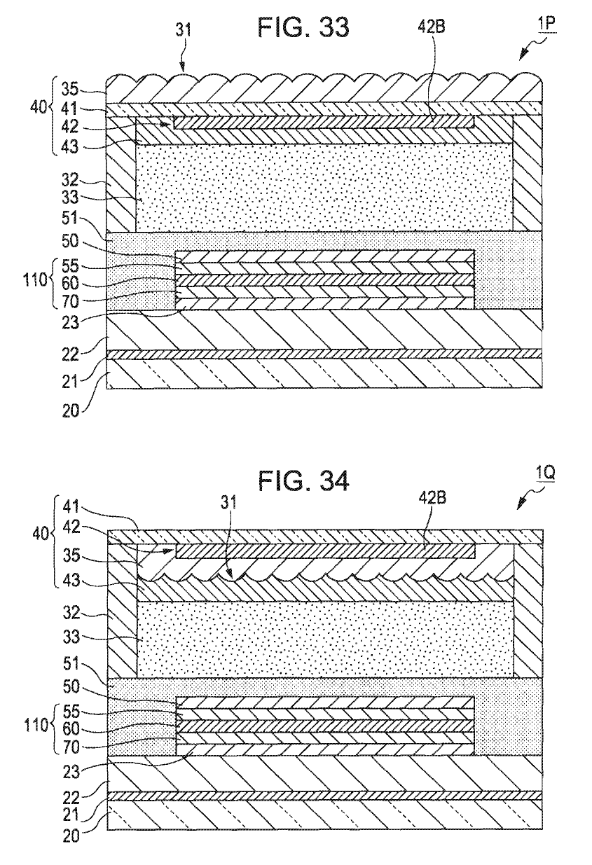

Additionally, as an interface in which the directive scattering layer 35 is formed in the color filter substrate 40 is not limited to the interface between the substrate 41 and the color filter layer 42B as shown in FIG. 31. For example, the directive scattering layer 35 may be disposed in an interface between the overcoat layer 43 and the filler 33 as an organic EL element 10 shown in FIG. 32, and an outer surface (a different surface from the surface on which the filler 33 is formed) of the substrate 41 as an organic EL element 1P shown in FIG. 33. Alternatively, it can be disposed in an interface between the color filter layer 42B and the overcoat 43 as an organic EL element 1Q shown in FIG. 34.

As described above, although the light-emitting device according to the embodiments of the invention has been described with reference to the several embodiments, the invention is not limited to the embodiments.

For example, the light-emitting device according to the embodiment includes the directive scattering layer 35 including the waveform structure 31 which is disposed in the interface between the substrate 41 and the color filter layer 42, but the directive scattering layer 35 can be formed in other interfaces of the thin films. Specifically, it can be disposed in one interface of the substrate 20, the reflection layer 21, the passivation layer 22, the pixel electrode 23, the hole transporting layer 70, the light-emitting layers 60, the electron transporting layer 55, the negative electrode 50, the filler 33, the overcoat layer 43, the color filter layer 42, and the substrate 41.

For instance, when the organic EL layer (the light-emitting layer) is formed by stacking two or more light-emitting layers so as to display white color with low-molecular organic EL, the configuration according to the embodiments of the invention can be applied. In this case, an interface for forming the directive scattering layer is not specially limited in the same way as the embodiment.

Herein, when there are two or more peaks of an emission spectrum, the light extraction efficiency can be increased and the viewing angle can be appropriately widened by overlapping two or more directive scattering layers including a waveform structure (that is, the waveform cycle is in the range of ±250 nm centered around the peak wavelength) having a configuration corresponding to two peak wavelengths. Additionally, when there is provided a directive scattering layer including a waveform structure (that is, the waveform cycle is in the range of ±250 nm centered around the peak wavelength) having a configuration corresponding one peak wavelength, about 1.2 to 1.5 times energy can be supplied to the air layer on the viewer side.

As mentioned above, when there are three peaks of an emission spectrum, the advantage of some aspects of the invention can be exhibited by forming a directive scattering layer including a waveform structure (that is, the waveform cycle is in the range of ±250 nm centered around the peak wavelength) having a configuration corresponding to each peak wavelength, forming a directive scattering layer including a waveform structure (that is, the waveform cycle is in the range of ±250 nm centered around the peak wavelength) having a configuration corresponding to two peak wavelengths, or forming a directive scattering layer including a waveform structure (that is, the waveform cycle is in the range of ±250 nm centered around the peak wavelength) having a configuration corresponding to one optional peak wavelength.

In an emission spectrum of two peaks of an emission spectrum, occasionally there is a case that a green emission intensity is particularly small and a color rendering function of a panel is not sufficient. In this case, the color rending function of the panel can be increased by forming a waveform structure (that is, the waveform cycle is in the range of ±250 nm centered around the peak wavelength) corresponding to a wavelength of a color having a small emission intensity so that the emission of the color having the small emission intensity is selectively and efficiently supplied to the air layer.

The full color organic EL element with a top emission type as shown in FIG. 3 can include a waveform structure (that is, the waveform cycle is in the range of ±250 nm centered around the peak wavelength) corresponding to a peak wavelength of an emission spectrum. Pixels disposed in a matrix arrangement can obtain the same directive scattering effect even when it is formed by coating with a luminous material by the use of a mask deposition method, white emission is generated by the use of a microcavity, and the luminous material coating and the microcavity are used together. Specifically, the waveform structure can be formed in matrix positions corresponding to color pixels by the use of luminous materials having a peak of 465 nm in a blue emission spectrum, a peak of 525 nm in a green emission spectrum, and a peak of 630 nm in a red emission spectrum. Herein, the waveform structure can be designed so that the waveform cycle is substantially in the range of 200 nm to 730 nm and an average of the waveform cycle is substantially 450 nm in a blue region, the waveform cycle is substantially in the range of 300 nm to 775 nm and an average of the waveform cycle is substantially 550 nm in a green region, and the waveform cycle is substantially in the range of 400 nm to 980 nm and an average of the waveform cycle is substantially 650 nm. In this case, 1.62 times energy can be supplied to the air layer on the viewer side more than the case that the waveform structure is not provided when white is displayed by turning on red, green, and blue pixels.

Such the waveform structure can be formed by performing methods such as a spin, a flexography printing, and an ink jet to an alkoxy silane solution several times so that a film thickness out of a mesoporous silica is in the range of 170 nm, 140 nm, and 135 nm. In this case, for example, it is possible to form a waveform structure which exhibits the directive scattering effect in a visible light region by forming the film thickness out of the mesoporous silica to be in the range of 40 nm to 200 nm or so. Additionally, it is possible to form a waveform structure which exhibits the directive scattering effect in wavelength regions of a red, a green, and a blue by forming the film thickness out of the mesoporous silica to be in the range of 110 nm to 140 nm, 140 nm to 159 nm, and 160 nm to 230 nm, respectively.

Other than forming the waveform structure corresponding to the wavelength of the color in respective color pixels, when there is a color of which the extraction efficiency is required to be increased so as to enhance a color taste of a panel, the waveform structure may be selectively formed in a portion corresponding to the pixel. Additionally, when there is one color of which the extraction efficiency is required to be increased in a full color display, a waveform structure including a waveform cycle corresponding to the peak wavelength of the color spectrum may be formed in the total surface of a substrate.

### Electronic Apparatus

Next, an electronic apparatus according to another aspect of the invention will be described.

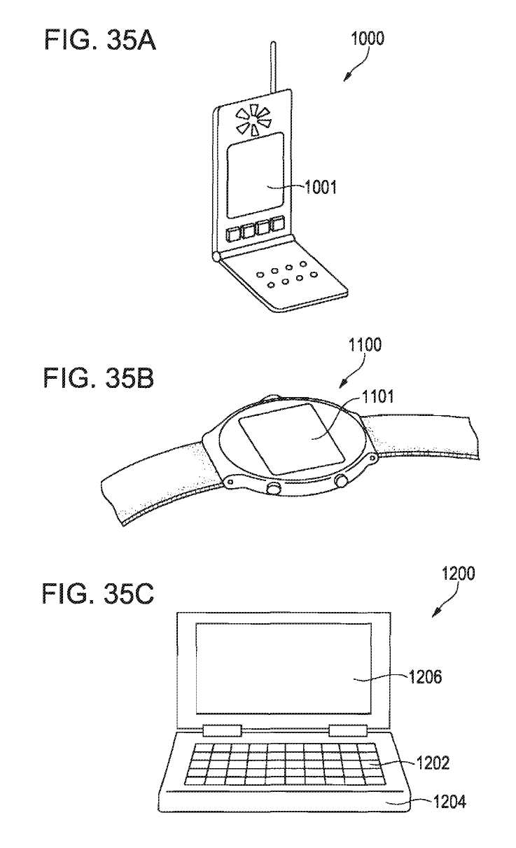

The electronic apparatus has the organic EL panel 1 as a display portion, that is, a specific example shown in FIG. 35.

FIG. 35A is a perspective view illustrating an example of a cellular phone. In FIG. 35A, a cellular phone 1000 includes a display portion 1001 using the organic EL panel 1.

FIG. 35B is a perspective view illustrating a wristwatch-type electronic apparatus. In FIG. 35B, a watch 1100 includes a display portion 1101 using the organic EL panel 1.

FIG. 35C is a perspective view illustrating an example of a portable information processing device such as a word processor and PC. In FIG. 35C, an information processing device 1200 includes an input portion 1201 for a keyboard, a display portion 1202 using the organic EL panel 1, and a main body 1203 of an information processing device.

The electronic apparatuses in FIGS. 35A to 35C, since there are provided the display portions 1001, 1101, and 1202 having the organic EL panel 1 (the organic EL device), the organic EL device constituting the display portion achieves a high brightness and a suppression of a color shift as well.

The entire disclosure of Japanese Application No. 2006-136168, filed May 16, 2006 is expressly incorporated by reference herein.

What is claimed is:

1. A light-emitting device in which a plurality of thin films including a light-emitting layer are stacked, the light-emitting device comprising:
a waveform structure having a directive scattering function in one interface between the thin films.

2. The light-emitting device according to claim 1, wherein the waveform structure includes a plurality of convex and concave portions randomly disposed and the convex and concave portions have a smooth surface.

3. The light-emitting device according to claim 2, wherein the distance between adjacent convex portions in the waveform structure is in the range of 300 nm to 1200 nm.

4. The light-emitting device according to claim 2, wherein the distance between adjacent convex portions in the waveform structure is in the range of −250 nm to +250 nm centered around a peak wavelength of a spectrum of an emission color in the light-emitting layer.

5. The light-emitting device according to claim 2, wherein the height between a convex top portion and a concave bottom portion in the waveform structure is in the range of 50 nm to 500 nm.

6. The light-emitting device according to claim 1, wherein the waveform structure occupies 30% or more of the total area of the interface between the thin films.

7. A method of fabricating a light-emitting device in which a plurality of thin films including a light-emitting layer are stacked, and the light-emitting device includes a waveform structure having a directive scattering function in one interface between the thin films, the method comprising:
a waveform structure forming process of forming a film made of mesoporous silica by the use of a spin coat method and forming the waveform structure.

8. The method according to claim 7, wherein a film forming condition of the waveform structure is designed so that the thickness of the film formed of the mesoporous silica is in the range of 10 nm to 300 nm.

9. The method according to claim 7, wherein the waveform structure forming process includes:
depositing a silicon alkoxide solution having a solid content in the range of 3 wt % to 8 wt % by the use of a spin coat method with a spin coat rotation speed in the range of 1500 rpm to 4000 rpm; and
performing a baking process in vacuum in the temperature range of 300 to 400° C. for 0.5 to 5 hours.

10. An electronic apparatus comprising the light-emitting device according to claim 1.
